(19) United States
(12) Patent Application Publication
(10) Pub. No.: US 2025/0052797 A1
(43) Pub. Date: Feb. 13, 2025

(54) PROPAGATION ENVIRONMENT ESTIMATION METHOD, PROPAGATION ENVIRONMENT ESTIMATION SYSTEM AND PROPAGATION ENVIRONMENT ESTIMATION DEVICE

(71) Applicant: NIPPON TELEGRAPH AND TELEPHONE CORPORATION, Tokyo (JP)

(72) Inventors: Ryotaro TANIGUCHI, Musashino-shi, Tokyo (JP); Tomoki MURAKAMI, Musashino-shi, Tokyo (JP); Tomoaki OGAWA, Musashino-shi, Tokyo (JP); Yasushi TAKATORI, Musashino-shi, Tokyo (JP); Minoru INOMATA, Musashino-shi, Tokyo (JP)

(73) Assignee: NIPPON TELEGRAPH AND TELEPHONE CORPORATION, Tokyo (JP)

(21) Appl. No.: 18/723,488

(22) PCT Filed: Dec. 24, 2021
(86) PCT No.: PCT/JP2021/048369

§ 371 Date: Jun. 24, 2024

(51) Int. Cl. G01R 29/08

(52) U.S. Cl. CPC G01R 29/0871

(57) ABSTRACT

The present disclosure relates to a propagation environment estimation method suitable for environment estimation of a wireless signal using a scale model. The method includes the following steps. The scale model is created. A light source regarded as a transmission station of the radio wave is installed in the scale model, and a measurement range in the scale model is irradiated by the light source. The measurement range irradiated by the light source is captured, and gradation of light obtained by the capture is converted into a reception level of the radio wave.

### TECHNICAL FIELD

The present disclosure relates to a propagation environment estimation method, a propagation environment estimation system, and a propagation environment estimation device, and more particularly, to a propagation environment estimation method, a propagation environment estimation device, and a propagation environment estimation system suitable for environment estimation of a wireless signal using a scale model.

### BACKGROUND ART

In recent years, with an explosive spread of wireless communication devices, demand for wireless communication has increased. Meanwhile, frequency resources that can be used for wireless communication are limited. Therefore, it is necessary to use a frequency that has not been used so far in addition to existing frequencies. In using a new frequency band, it is necessary to investigate in advance a propagation characteristic of a wireless signal in a service area, an influence of interference of a signal of the new frequency band on another system, and the like.

Under such demands, for example, in the radio communication sector (ITU-R) of International Telecommunication Union (ITU), attempts have been made to actually measure propagation characteristics of radio signals in a real area and formulate a propagation model from various measurement results. However, in this type of attempt, there are problems that a measurement result for an undeveloped frequency is not sufficient, a propagation model is not sufficiently formulated, and the like.

Non Patent Literature 1 below discloses a method for reproducing characteristics of a propagation loss in a mobile communication environment using a scale model. FIG. 1 is a schematic diagram illustrating a state in which a propagation model is estimated by actual measurement in a real area and a state in which model estimation by actual measurement is performed using a scale model in comparison.

As illustrated in FIG. 1, in the method using the scale model, for example, the scale model is produced for a real city area or the like at a scale of 1/100 or the like. Then, a radio signal is generated under the environment of the scale model, and propagation characteristics of radio waves of the wireless signal is measured. According to such a method, cost required for collecting necessary data can be substantially reduced as compared with a case where the propagation environment is actually measured in a real city area.

### CITATION LIST

### Non Patent Literature

Non Patent Literature 1: “Establishment of scale model method for radio wave propagation”, Shinichi ICHITSUBO, Scientific Research Grant Program (Scientific Research Grant), Research Result Report, May 18, 2012

### SUMMARY OF INVENTION

### Technical Problem

As described above, in the conventional method using the scale model, the propagation environment is estimated by actually measuring behavior of radio waves under the environment of the scale model. Since the measurement is performed using radio waves, for example, actual measurement work is required for the number of measurement places in order to perform measurement at a plurality of places in the area. That is, it is necessary to install measurement devices as many as the number of places where data is to be measured and to individually perform measurement at each place. For this reason, the above-described existing technique requires a lot of time and effort when propagation characteristics of a radio signal in a service area need to be obtained in a planar manner.

The present disclosure has been made in view of the above problems, and a first object of the present disclosure is to provide a propagation environment estimation method for more easily estimating a planar reception level in an area in a shorter time than an existing propagation characteristic estimation method using a scale model.

Further, a second object of the present disclosure is to provide a propagation environment estimation system for more easily estimating a planar reception level in an area in a shorter time than an existing propagation characteristic estimation method using a scale model.

Moreover, a third object of the present disclosure is to provide a propagation environment estimation device for more easily estimating a planar reception level in an area in a shorter time than an existing propagation characteristic estimation method using a scale model.

### Solution to Problem

The first aspect is, to achieve the above object, a propagation environment estimation method for estimating a propagation environment of a radio wave using a scale model, and desirably includes:
a step of creating a scale model;
a step of installing, in the scale model, a light source regarded as a transmission station of a radio wave;
a step of irradiating a measurement range in the scale model by the light source;
a step of capturing the measurement range irradiated by the light source; and
a calibration step of converting gradation of light obtained by the capture into a reception level of the radio wave.

Further, the second aspect is a propagation environment estimation system that estimates a propagation environment of a radio wave using a scale model, and desirably includes:
a 3D printer that creates a scale model;
an element mounter that installs, in the scale model, a light source regarded as a transmission station of a radio wave;
a control device that causes the light source to irradiate a measurement range in the scale model; and
a capturing device that captures the measurement range irradiated by the light source, in which
the control device is configured to execute calibration processing of converting gradation of light obtained by the capture into a reception level of the radio wave.

Further, the third aspect is a propagation environment estimation device that estimates a propagation environment of a radio wave using a scale model, and desirably includes:
a 3D printer unit that creates a scale model;
an element mounter unit that installs, in the scale model, a light source regarded as a transmission station of a radio wave;
a control device unit that causes the light source to irradiate a measurement range in the scale model; and
a capturing device unit that captures the measurement range irradiated by the light source, in which
the control device unit is configured to execute calibration processing of converting gradation of light obtained by the capture into a reception level of the radio wave.

### Advantageous Effects of Invention

According to the first to third aspects, it is possible to more easily estimate a planar reception level in an area in a shorter time than an existing propagation characteristic estimation method using a scale model.

### BRIEF DESCRIPTION OF DRAWINGS

FIG. 1 is a schematic diagram illustrating a state in which a propagation model is estimated by actual measurement in a real area and a state in which model estimation by actual measurement is performed using a scale model in comparison;

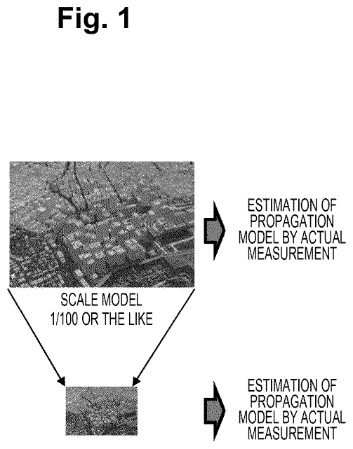

FIG. 2 is a diagram for describing an outline of a propagation environment estimation method according to a first embodiment of the present disclosure;

FIG. 3 is a diagram for describing one of points to be noted in determining a scale of a scale model in the propagation environment estimation method according to the first embodiment of the present disclosure;

FIG. 4 is a flowchart for describing a flow of processing when estimating a propagation environment according to the propagation environment estimation method of the first embodiment of the present disclosure; and

FIG. 5 is a block diagram for describing a configuration of a propagation environment estimation system that continuously performs a series of processing illustrated in FIG. 4 in a fully automatic manner.

### DESCRIPTION OF EMBODIMENTS

### First Embodiment

### Outline of First Embodiment

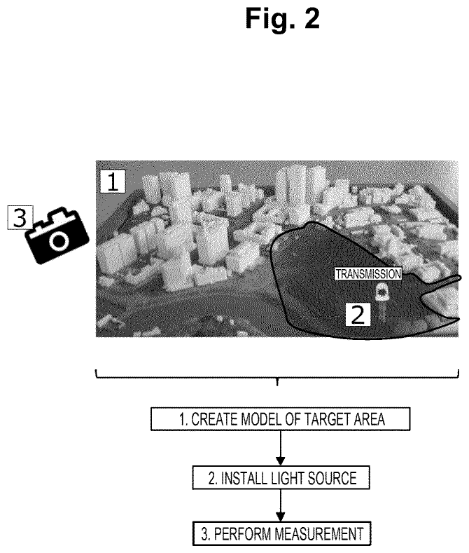

FIG. 2 is a diagram for describing an outline of a propagation environment estimation method according to a first embodiment of the present disclosure. More specifically, an upper part of FIG. 2 illustrates a perspective view of a scale model used in the propagation environment estimation method of the present embodiment. Further, a lower part of FIG. 2 illustrates a flowchart for describing an outline of the propagation environment estimation method of the present embodiment. The numbers “1”, “2”, and “3” illustrated in the upper part of FIG. 2 respectively correspond to numbers of steps illustrated in the lower part of FIG. 2.

The propagation environment estimation method according to the present embodiment is suitable as a method for investigating a propagation characteristic of a wireless signal in a service area in advance in a case where a wireless communication service is newly started. Typically, the service area is assumed to be an urban area where many buildings exist.

As illustrated in FIG. 2, in the propagation environment estimation method of the present embodiment, estimation of a propagation environment is advanced by the following procedure.

1. A model of the target area is created. Hereinafter, this model is referred to as a “scale model”. The scale model reproduces a real urban space or the like at a scale of about 1/100, for example. FIG. 2 illustrates an example in which an outdoor space is set as the target area, but an indoor space of a specific building may be set as the target area.

2. A light source is installed as a transmission source of radio waves. As the light source, for example, a light emitting diode, an incandescent lamp, or the like can be used. It is also possible to use laser light having excellent straightness on the premise that high-speed scanning is performed to such an extent that a measurement range can be substantially two-dimensionally or three-dimensionally irradiated.

3. The measurement range in which estimation of the propagation environment is required is captured as a photograph. More specifically, gradation of light in the measurement range is imaged by an image sensor. Next, calibration processing for converting the gradation of light into radio wave intensity is applied to the captured image, and a reception level of the radio wave is planarly acquired.

### Points to be Noted in First Embodiment

(1) In creating the scale model of the target area, it is necessary to appropriately determine what scale is adopted. In the present embodiment, representatively, the following points are noted in determining the scale.

### (1-a) Installation Space for Element or the Like

As described above, in the present embodiment, it is necessary to install a light emitting element regarded as a transmission source of radio waves in the scale model. Further, in a case where it is desired to estimate an accurate reception level for a specific place, it may be necessary to install the light receiving element regarded as a receiver of radio waves at the place.

These elements are installed on a road or in a square in the target area. Then, the installation space changes according to the scale of the scale model, and if an excessive scale is adopted, a situation where these elements cannot be installed at the corresponding place of the scale model. Therefore, in the present embodiment, the scale of the scale model is determined so that various elements required for estimating the propagation characteristic do not interfere with a building or the like.

### (1-b) Reaching Distance of Measurement Light

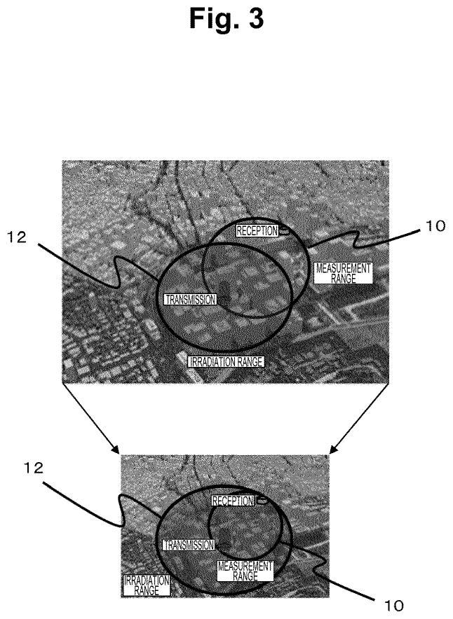

FIG. 3 illustrates two types of scale models with different scales in comparison. More specifically, the upper part of FIG. 3 illustrates a scale model with a large scale, and the lower part of FIG. 3 illustrates a scale model with a small scale. In each scale model, an area where the propagation characteristic is desired to be measured is indicated as a “measurement range” 10. Further, an arrival circle of light emitted from the light source regarded as a transmission source of radio waves is illustrated as an “irradiation range” 12.

In the scale model in the upper part of FIG. 3, a region beyond the irradiation range 12 of the light source is generated in a part of the measurement range 10 due to the too large scale. In this case, even if a result of irradiation by the light source is captured, desired data cannot be obtained for the entire measurement range 10. On the other hand, in the scale model in the lower part of FIG. 3, the entire measurement range 10 is covered with the irradiation range 12. In this case, by capturing the result of irradiation by the light source, desired data can be obtained for the entire measurement range 10. In view of such circumstances, in the present embodiment, the scale of the scale model is determined such that the entire measurement range 10 falls within the irradiation range 12 without excess or deficiency, as illustrated in the lower part of FIG. 3.

(2) It is desirable that behavior of the light regarded as the radio waves is consistent with behavior of the radio waves in a real area. In a propagation characteristic estimation method of the present embodiment, the following points are taken into consideration in order to meet the above requirements.

### (2-a) Reflectance of Radio Waves and Light

Reflectance of the radio waves in each part of the target area is reflected in the behavior of the radio waves. Similarly, the behavior of the light emitted from the light source is affected by the reflectance of the light in each part of the scale model. In the present embodiment, surface treatment is applied to each part of the scale model so that the reflectance of the radio waves in each part of the target area is consistent with the reflectance of the light in each part of the scale model. The surface treatment is performed by, for example, applying a coating material, texturing a model wall surface, or the like.

### (2-b) Attenuation Rate of Radio Waves and Light

Intensity of the radio waves attenuates according to a distance from the transmission source. The attenuation rate is affected by the frequency of the radio waves. On the other hand, the intensity of light also exhibits attenuation according to a wavelength of light according to the distance from the light source. In the present embodiment, to replace the attenuation of the light in the scale model with the attenuation of the radio waves in the target area, calibration processing is applied to gradation of the light captured in the scale model. The calibration processing is performed by, for example, multiplying a ratio between the attenuation rate of the radio waves in the target area and the attenuation rate of the light actually measured in the scale model by the gradation of the captured light.

### (2-c) Frequency Characteristics of Radio Waves and Wavelength Characteristics of Light

The behavior of the radio waves in the real target area is affected by the frequency. To estimate the actual behavior of the radio waves from the behavior of the light in the scale model, it is desirable that the light used in the scale model exhibits behavior similar to that of the actual radio waves. In the present embodiment, the wavelength of light used for the light source is appropriately selected in order to meet the above requirements. Specifically, in the present embodiment, several light sources each emitting light of red, blue, yellow, or the like are prepared, and the light source is appropriately selected according to the radio wave to be used in the target area.

### Details of Procedures in First Embodiment

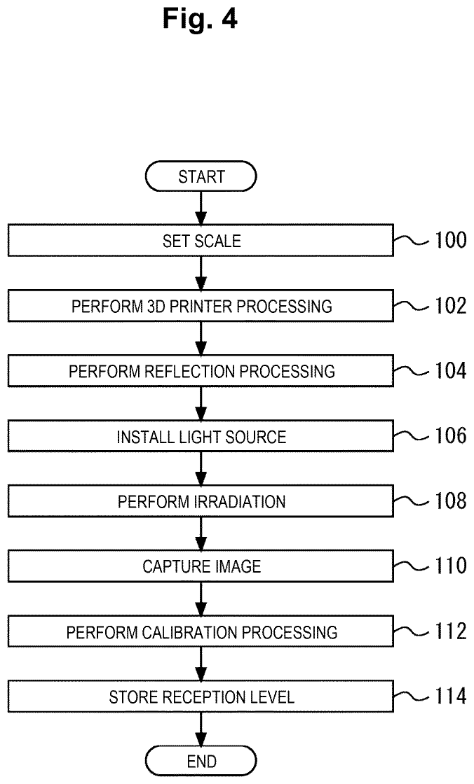

FIG. 4 is a flowchart for describing a procedure of a propagation environment estimation method of the present embodiment in detail. The procedure illustrated in FIG. 4 is started when collection of information such as dimensions and locations of buildings and roads, the reflectance of the radio waves at main points, and the frequency of the radio waves scheduled to be used is completed for the real target area, and specifications of the light source and the like used for measurement are determined.

As illustrated in FIG. 4, in this procedure, first, the scale of the scale model to be created is determined (step 100). In present step 100, with attention being paid to the above points (1-a) and (1-b), a scale without excess or deficiency is determined under essential conditions that the elements such as the light source can be installed and that the irradiation range 12 by the light source covers the entire measurement range 10.

Next, the scale model is created by a 3D printer (step 102). Here, first, information regarding dimensions and arrangement of various buildings and the like existing in the target area is provided to the 3D printer together with the above-described scale. The 3D printer creates the scale model of the target area according to the provided scale.

When the processing of the 3D printer is completed, next, reflection processing is applied to the created scale model (step 104). For example, coating treatment, surface treatment, or the like for adjusting the reflectance of light with the reflectance of the radio waves is applied to the model wall surface of the building. The reflection processing in present step may be manually performed by an operator. Alternatively, the coating treatment may be performed by a fully automatic coating device capable of three-dimensionally specifying a coating place. Further, the surface treatment may be implemented by processing using a 3D printer.

Next, the light source regarded as a transmission station of radio waves is installed (step 106). The light source is installed at an installation proposed location of the transmission station in the scale model. The light source may be manually installed by an operator or may be installed by a fully automatic element mounter without manual operation.

When the above preparation is completed, next, irradiation of the scale model by the light source is started (step 108). In a case where the light source is a light emitting diode or an incandescent lamp, lighting processing for the light source is performed in present step 108. In a case where the light source is a laser beam having high straightness, scanning with the laser beam is started such that the entire measurement range 10 is illuminated with the laser beam.

When the irradiation by the light source is started, next, the measurement range 10 is captured (step 110). The capture may be manually performed by an operator or may be performed using a capturing device capable of fully automatically capturing a specified area.

When the capture of the measurement range 10 is completed, next, the calibration processing is performed (step 112). Specifically, first, an image of the measurement range 10 acquired by the capture is read. Next, the gradation of light appearing in the image is quantified. That is, a numerical value representing the intensity of light is determined for each pixel constituting the image. Then, the reception level of the radio waves is calculated for each pixel by calculating the ratio of the attenuation rates described in (2-b) above for each pixel, and multiplying the above numerical value and the above ratio for each pixel.

Finally, a set of values for each pixel calculated in step 112 above is stored as information that planarly indicates the reception level of the radio waves (step 114).

### [Propagation Environment Estimation System of First Embodiment]

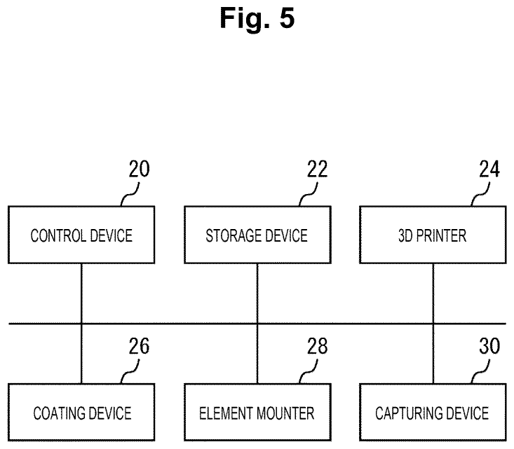

FIG. 5 is a block diagram for describing a configuration of a propagation environment estimation system capable of continuously performing the series of processing illustrated in FIG. 4 in a fully automatic manner. The system illustrated in FIG. 5 includes a control device 20 and a storage device 22. The control device 20 includes an arithmetic processing unit. The storage device 22 stores a program to be executed by the arithmetic processing unit. The control device 20 controls each unit of the system illustrated in FIG. 5 by the arithmetic processing unit proceeding with processing according to the above-described program.

The storage device 22 stores various types of information regarding the target area in addition to the above-described program. This information includes the dimensions and locations of buildings, roads, and the like, the reflectance of the radio waves, and the like. The storage device 22 also stores dimensional data of various elements that can be used in the scale model. Furthermore, the storage device 22 also stores the result of measurement performed using the scale model, that is, information of the planar reception level obtained in the processing of step 112.

The system illustrated in FIG. 5 includes a 3D printer 24. The control device 20 reads the various types of information from the storage device 22 and performs the processing of step 100 described above, that is, the scale determination processing. The 3D printer reads the information regarding the target area from the storage device 22, and cuts out the scale model at the scale determined by the control device 20. In a case where texture processing needs to be applied to a specific portion in order to make the reflectance of the radio waves and the reflectance of the measurement light uniform, the processing is also performed by the 3D printer 24.

The system illustrated in FIG. 5 includes a coating device 26. The coating device 26 includes a coating material nozzle that can three-dimensionally move, and can apply a desired coating material to an arbitrary position of the scale model. In response to a command from the control device 20, the coating device 26 can apply coating for obtaining the desired reflectance to a specified position of the scale model on the basis of the information read from the storage device 22.

The system illustrated in FIG. 5 includes an element mounter 28. The element mounter 28 has a function to install an element scheduled to be used in the scale model at an arbitrary position of the scale model. In the present embodiment, an element that functions as the light source is installed by the element mounter 28 in accordance with a command from the control device 20.

The system illustrated in FIG. 5 further includes a capturing device 30. The capturing device 30 can capture an arbitrary area of the scale model as the measurement range 10. Data of an image captured by the capturing device 30 is stored in the storage device 22. The control device 20 can planarly estimate the reception level of the radio waves generated in the measurement range 10 by applying the configuration processing in step 112 to image data stored in the storage device 22. The estimated reception level is stored in the storage device 22 as described above.

As described above, according to the propagation environment estimation method of the present embodiment, it is possible to accurately estimate the planar information regarding the reception level of the radio waves by the simple processing using the scale model. Therefore, according to the estimation method of the present embodiment, the cost required for estimating the propagation environment of the target area can be substantially reduced.

Further, according to the propagation environment estimation system described with reference to FIG. 5, the propagation environment estimation method of the present embodiment can be advanced as a fully automatic procedure in a straight manner. Therefore, according to this system, work efficiency regarding the estimation of the propagation environment of the target area can be significantly improved.

Meanwhile, in the above-described first embodiment, the configuration illustrated in FIG. 5 has been described as a system including a plurality of devices, but the present disclosure is not limited thereto. That is, the configuration illustrated in FIG. 5 may be a single device in which the illustrated elements are housed in a single housing.

### REFERENCE SIGNS LIST

10 Measurement range
12 Irradiation range
20 Control device
22 Storage device
24 3D printer
26 Coating device
28 Element mounter
30 Capturing device

1. A propagation environment estimation method for estimating a propagation environment of a radio wave using a scale model, the propagation environment estimation method comprising:
creating a scale model;
installing, in the scale model, a light source regarded as a transmission station of a radio wave;
irradiating a measurement range in the scale model by the light source;
capturing the measurement range irradiated by the light source; and
calibrating gradation of light obtained by the capture for converting it into a reception level of the radio wave.

2. The propagation environment estimation method according to claim 1, further comprising: setting a scale of the scale model prior to the creation of the scale model,
the setting of the scale including:
acquiring information regarding an installation space of the transmission station in a target area;
acquiring dimensions of the light source; and
setting the scale such that the light source is accommodated in a corresponding portion of the installation space in the scale model.

3. The propagation environment estimation method according to claim 1, further comprising: setting a scale of the scale model prior to the creation of the scale model,
the setting of the scale including:
acquiring information of a range in which a propagation environment of the radio wave is to be measured in a target area;
recognizing a portion of the scale model corresponding to said range as the measurement range;
acquiring information of an irradiation range by the light source; and
setting the scale such that the measurement range falls within the irradiation range.

4. The propagation environment estimation method according to claim 1, further comprising applying reflection treatment to at least a part of the scale model such that a light reflectance in the scale model matches a radio wave reflectance in a target area.

5. The propagation environment estimation method according to claim 1, further comprising setting a wavelength of light emitted from the light source on a basis of a frequency of the radio wave assumed to be used in a target area such that a behavior of light in the scale model matches a behavior of the radio wave in the target area.

6. The propagation environment estimation method according to claim 1, wherein
the calibration of the gradation of light includes:
acquiring an attenuation characteristic of the radio wave in a target area;
acquiring an attenuation characteristic of light emitted from the light source in the scale model, and
calibrating the gradation of the light on a basis of the attenuation characteristic of the radio wave and the attenuation characteristic of the light.

7. A propagation environment estimation system that estimates a propagation environment of a radio wave using a scale model, the propagation environment estimation system comprising:
a 3D printer that creates a scale model;
an element mounter that installs, in the scale model, a light source regarded as a transmission station of a radio wave;
a controller that causes the light source to irradiate a measurement range in the scale model; and
a camera that captures the measurement range irradiated by the light source, wherein
the controller is configured to execute calibration processing of converting gradation of light obtained by the capture into a reception level of the radio wave.

8. A propagation environment estimation device that estimates a propagation environment of a radio wave using a scale model, the propagation environment estimation device comprising:
a 3D printer that creates a scale model;
an element mounter that installs, in the scale model, a light source regarded as a transmission station of a radio wave;
a controller that causes the light source to irradiate a measurement range in the scale model; and
a camera that captures the measurement range irradiated by the light source, wherein
the controller is configured to execute calibration processing of converting gradation of light obtained by the capture into a reception level of the radio wave.

9. The propagation environment estimation method according to claim 2, further comprising: setting a scale of the scale model prior to the creation of the scale model,
the setting of the scale including:
acquiring information of a range in which a propagation environment of the radio wave is to be measured in a target area;
recognizing a portion of the scale model corresponding to said range as the measurement range;
acquiring information of an irradiation range by the light source; and
setting the scale such that the measurement range falls within the irradiation range.

10. The propagation environment estimation method according to claim 2, further comprising applying reflection treatment to at least a part of the scale model such that a light reflectance in the scale model matches a radio wave reflectance in a target area.

11. The propagation environment estimation method according to claim 3, further comprising applying reflection treatment to at least a part of the scale model such that a light reflectance in the scale model matches a radio wave reflectance in a target area.

12. The propagation environment estimation method according to claim 9, further comprising a step of applying reflection treatment to at least a part of the scale model such that a light reflectance in the scale model matches a radio wave reflectance in a target area.

13. The propagation environment estimation method according to claim 2, further comprising setting a wavelength of light emitted from the light source on a basis of a frequency of the radio wave assumed to be used in a target area such that a behavior of light in the scale model matches a behavior of the radio wave in the target area.

14. The propagation environment estimation method according to claim 3, further comprising setting a wavelength of light emitted from the light source on a basis of a frequency of the radio wave assumed to be used in a target area such that a behavior of light in the scale model matches a behavior of the radio wave in the target area.

15. The propagation environment estimation method according to claim 4, further comprising setting a wavelength of light emitted from the light source on a basis of a frequency of the radio wave assumed to be used in a target area such that a behavior of light in the scale model matches a behavior of the radio wave in the target area.

16. The propagation environment estimation method according to claim 12, further comprising setting a wavelength of light emitted from the light source on a basis of a frequency of the radio wave assumed to be used in a target area such that a behavior of light in the scale model matches a behavior of the radio wave in the target area.

17. The propagation environment estimation method according to claim 2, wherein
the calibration of the gradation of light includes:
acquiring an attenuation characteristic of the radio wave in a target area;
acquiring an attenuation characteristic of light emitted from the light source in the scale model, and
calibrating the gradation of the light on a basis of the attenuation characteristic of the radio wave and the attenuation characteristic of the light.

18. The propagation environment estimation method according to claim 3, wherein
the calibration of the gradation of light includes:
acquiring an attenuation characteristic of the radio wave in a target area;
acquiring an attenuation characteristic of light emitted from the light source in the scale model, and
calibrating the gradation of the light on a basis of the attenuation characteristic of the radio wave and the attenuation characteristic of the light.

19. The propagation environment estimation method according to claim 4, wherein
the calibration of the gradation of light includes:
acquiring an attenuation characteristic of the radio wave in a target area;
acquiring an attenuation characteristic of light emitted from the light source in the scale model, and
calibrating the gradation of the light on a basis of the attenuation characteristic of the radio wave and the attenuation characteristic of the light.

20. The propagation environment estimation method according to claim 16, wherein
the calibration of the gradation of light includes:
acquiring an attenuation characteristic of the radio wave in a target area;
acquiring an attenuation characteristic of light emitted from the light source in the scale model, and
calibrating the gradation of the light on a basis of the attenuation characteristic of the radio wave and the attenuation characteristic of the light.
